(19) United States
(12) Patent Application Publication
(10) Pub. No.: US 2020/0176272 A1
(43) Pub. Date: Jun. 4, 2020

(54) METAL BASED CERAMIC FILLERS AS CATALYSTS FOR SELECTIVE ELECTROLESS METAL PLATING

(71) Applicant: Intel Corporation, Santa Clara, CA (US)

(72) Inventors: Vivek RAGHUNATHAN, Mountain View, CA (US); Yonggang LI, Chandler, AZ (US)

(21) Appl. No.: 16/325,100

(22) PCT Filed: Sep. 30, 2016
(86) PCT No.: PCT/US2016/055019

§ 371 Date: Feb. 12, 2019

(51) Int. Cl. H01L 21/48; H01L 23/498

(52) U.S. Cl. CPC H01L 21/4857; H01L 23/49822; H01L 23/49866; H01L 21/486

(57) ABSTRACT

Embodiments include methods for selective electroless plating of dielectric layers and devices formed by such processes. According to an embodiment, patterned surfaces are formed in a dielectric layer that includes metallic ceramic fillers. In some embodiments, the patterned surfaces form a line opening and a via opening that exposes a conductive pad. In an embodiment, the metallic ceramic fillers are activated to form activated surfaces over the patterned surfaces. A first metal is then deposited into the via opening with a first electroless solution that is a bottom-up deposition process. Thereafter, embodiments include forming a seed layer over exposed portions of the activated surfaces. In an embodiment, mid-gap states of the activated surfaces have an energy level approximately equal to a reduction potential of metal ions in a second electroless solution. Embodiments may then include depositing a second metal into the via opening with a third electroless solution.

### FIELD OF THE INVENTION

Embodiments of the present invention relate generally to electroless metal plating. In particular, embodiments of the present invention relate to methods for forming conductive features in the electronics packaging with a filler catalyzed selective plating (FCSP) process.

### BACKGROUND AND RELATED ARTS

High density interconnection (HDI) substrate patterning is typically performed with semi-additive patterning (SAP). SAP requires eight major processing operations to form the conductive traces and vias in each dielectric layer. First, a dielectric material is formed over an existing layer and thermally cured. Vias are then formed (e.g., with laser drilling) through the dielectric layer to provide connections to the lower layer. An electroless seed layer is then deposited onto all exposed surfaces. In order to prevent metal deposition across the entire surface, a resist layer is formed over the exposed surfaces and then patterned. The patterning exposes only regions of the dielectric layer on which metal is desired in order to form the conductive traces and vias. The resist layer is then developed, typically in a liquid solution, to remove the resist where metal is desired. Electrolytic plating then metalizes the exposed surfaces of the dielectric layer. The resist layer may then be removed. Finally, the seed layer that was formed over the regions that were not metallized is removed. When it comes to very fine line and spacing a photosensitive dielectric may need to be used, for which a lithography process is used to form the vias. In that case multiple process operations will be added to the flow.

However, in SAP processes, photoresist adhesion to underlying dielectric and the copper etching process limits the FLS resolution to around 5/5 μm. Also, in SAP the presence of traces on the dielectric results in local unit level undulation thereby, limiting the scalability to smaller FLS (due to low depth of focus (DoF) of lithography exposure) while simultaneously resulting in high chip side thickness variation (CTV) during the die mount process.

### BRIEF DESCRIPTION OF THE DRAWINGS

FIG. 1A is a cross-sectional illustration of a build-up structure, according to an embodiment of the invention.

FIG. 1B is a cross-sectional illustration of the build-up structure in FIG. 1A after a via opening and line openings are formed into the build-up structure and metallic ceramic fillers in the build-up structure are activated to form activated surfaces over the patterned surfaces, according to an embodiment of the invention.

FIG. 1C is a cross-sectional illustration of the build-up structure in FIG. 1B after a conductive material is plated into the via opening and the line openings to form a via and conductive traces, according to an embodiment of the invention.

FIG. 2A is an illustration of a band diagram of a metallic ceramic filler and an electroless solution, according to an embodiment of the invention.

FIG. 2B is an illustration of a band diagram of an activated metallic ceramic filler and an electroless solution, according to an embodiment of the invention.

FIG. 3A is a cross-sectional illustration of a build-up structure, according to an embodiment of the invention.

FIG. 3B is a cross-sectional illustration of the build-up structure in FIG. 3A after a via opening and line openings are formed into the build-up structure and metallic ceramic fillers in the build-up structure are activated to form activated surfaces over the patterned surfaces, according to an embodiment of the invention.

FIG. 3C is a cross-sectional illustration of the build-up structure in FIG. 3B after the via is formed with a bottom-up metal deposition process, according to an embodiment of the invention.

FIG. 3D is a cross-sectional illustration of the build-up structure in FIG. 3C after a seed layer is formed over the exposed portions of the activated surfaces, according to an embodiment of the invention.

FIG. 3E is a cross-sectional illustration of the build-up structure in FIG. 3D after a bulk conductive material is deposited over the seed layer to form conductive traces, according to an embodiment of the invention.

FIG. 4 is a plan view illustration of a panel that includes multiple units of the build-up structures, according to an embodiment of the invention.

FIG. 5 is a cross-sectional illustration of a device package that includes build-up structures, according to an embodiment of the invention.

FIG. 6 is a schematic diagram of a computing device that utilizes a device package having dielectric and conductive layers formed in accordance with in an embodiment.

### DETAILED DESCRIPTION

Described herein are systems that include electronics packaging and methods for forming conductive features in the electronics packaging with a filler catalyzed selective plating (FCSP) process. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Embodiments of the invention include traces that are embedded within a dielectric layer. The use of embedded traces allows for smaller FLS and low CTV. However, embedding traces typically requires selective plating of trenches that are patterned into the dielectric layer. Selective plating is desired because it simplifies the process flow and reduces the cost of fabrication. In embodiments of the invention, the selective plating is enabled by incorporating metallic ceramic fillers into the dielectric layer. Once activated, the metallic ceramic fillers catalyze selective electroless metal deposition in laser ablated regions, thereby enabling embedded architectures that allow for ultra-fine trace width and spacing, such as 2/2 μm.

Embodiments of the invention may include a plating process that is referred to herein as filler catalyzed selective plating (FCSP) of dielectric layers. According to an embodiment, FCSP utilizes a dielectric layer that includes a metallic ceramic that is activated with a laser assisted local activation. In some embodiments, the laser assisted local activation may be the same process as the patterning process used to form the line openings and via openings in the dielectric. The activation of the metallic ceramic generates localized defects that increase the localized density of electrons. When the energy level of the defect is approximately equal to the redox potential of the plating metal, the localized defects catalyze the metal deposition in an electroless plating process. As such, metal is only deposited on the patterned surfaces of the dielectric layer. In another embodiment of the invention, the metallic ceramic may be utilized to implement an incremental FCSP process. An incremental FCSP process is particularly useful during the formation of high aspect ratio features. For example, high aspect ratio vias may be formed with a bottom-up deposition process that minimizes sidewall deposition in the via opening, thereby reducing the likelihood of void formation in the via. Thereafter, a second plating process may be implemented to form the conductive traces in the line openings. In the second plating process, the deposition of metal along sidewalls does not pose a concern due to the smaller aspect ratios of the line openings. The incremental plating process also alleviates the process restrictions and makes it easier to control the variation of the critical dimensions of the metal traces.

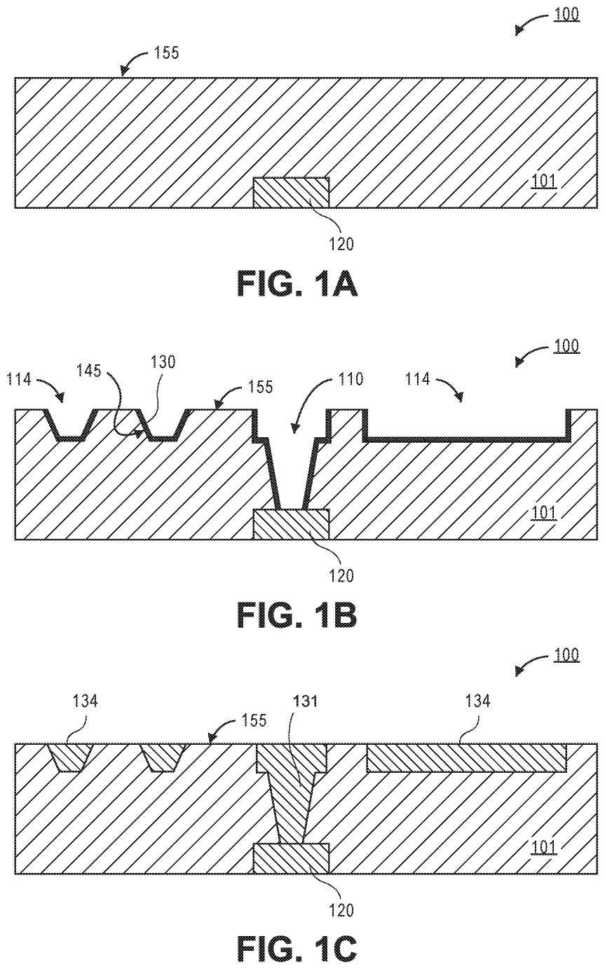

Referring now to FIGS. 1A-1C, cross-sectional illustrations of a dielectric layer that is patterned and metalized with a FCSP process are shown, according to an embodiment of the invention. In an embodiment, laser assisted local activation selectively activates metallic ceramic fillers that are included in the dielectric layer. After the metallic ceramic fillers have been activated, the dielectric layer is metallized with an electroless deposition process to selectively form metal connections only on the patterned surfaces of the dielectric layer.

Referring now to FIG. 1A, a cross-section illustration of a build-up structure 100 is shown, according to an embodiment. The build-up structure 100 includes a dielectric layer 101 formed over a contact 120. Contacts 120 may provide electrical connections to a lower dielectric layer (not shown) formed in the build-up structure 100. In an embodiment, dielectric layer 101 may be the first layer of a build-up structure, and therefore, certain embodiments do not include forming the dielectric layer over existing contacts 120. In an embodiment, the dielectric layer 101 is formed over a build-up structure core layer (not shown). According to an embodiment, the dielectric layer 101 may be an organic or inorganic material. By way of example, and not by way of limitation, the dielectric layer 101 may be a polyimide or an epoxy material. According to an embodiment, the dielectric layer 101 may be a resin based material. In an embodiment, dielectric layer 101 is laminated over an existing layer. In alternative embodiments, the dielectric layer 101 may be a liquid based material, and may be spun on over the surface of an existing layer. Embodiments include cured and partially cured dielectric layers 101. By way of example, and not by way of limitation, a partially cured dielectric layer 101 may be approximately 90% cross-linked or greater. As shown in FIG. 1A, dielectric layer 101 has a top unpatterned surface 155.

According to an embodiment, metallic ceramic fillers may be dispersed through the dielectric layer 101. The metallic ceramic fillers may be mixed into the dielectric material while the dielectric material is in a liquid phase prior to being deposited onto the build-up structure 100. According to an embodiment, the concentration of the metallic ceramic fillers may be approximately 1% (by weight) or less. In embodiments, the metallic ceramic fillers are materials that, when activated, include mid-gap defect states that have an energy state that is approximately equal to the redox potential of the subsequently plated metal. In an embodiment, the metallic ceramic fillers may include one or more of Al₂O₃, AlN, CeO₂, ZrO₂, and the like. A more detailed explanation of the activation process is provided below.

Referring now to FIG. 1B, the top unpatterned surface 155 of the dielectric layer 101 is patterned with a patterning process to form patterned surfaces 145 in the dielectric layer 101. According to an embodiment, the pattern may comprise one or more via openings 110 that provide an opening through dielectric layer 101 to the electrical contact 120 formed on a lower layer and/or one or more line openings 114. According to embodiments, the pattern may be formed with a patterning process such as direct laser writing, laser projection patterning, plasma etching, or other known patterning processes.

In an embodiment, the via openings 110 may be formed with a first patterning process, and the line openings 114 may be formed with a second patterning process. The first patterning process used to form the via openings 110 may be a different patterning process than the second patterning process. For example, the first patterning process may include laser ablation, and the second patterning process may include a plasma etching process. Additional embodiments include first and second patterning processes that are the same process. For example, both the first and second patterning processes may include a laser ablation process. According to such an embodiment, the laser intensity may be the same for the first and second patterning processes. Alternatively, the first and second patterning processes may use different laser intensities. In an embodiment, the intensity of a laser for a direct laser writing process may be between 0.5 J/cm² and 3 J/cm². In an additional embodiment, the via openings 110 and the line openings 114 may be formed with a single patterning process.

According to an embodiment, laser assisted local activation may activate the metallic ceramic fillers that are included in the dielectric layer 101. Accordingly, an activated layer 130 is illustrated as being formed over the patterned surfaces 145. Using laser assisted local activation allows for the activated layer 130 to be selectively formed only on the patterned surfaces 145 of the dielectric layer 101. According to an embodiment, laser assisted local activation is performed during the patterning process. For example, when the dielectric layer 101 is patterned with laser ablation, laser assisted local activation may be performed simultaneously with the patterning process (i.e., the laser assisted local activation is the same process as the laser ablation patterning process). Additional embodiments include laser assisted local activation that is performed after the patterning process. For example, a plasma etching process may be used to form the patterned surfaces 145, and thereafter, the laser assisted local activation may be performed to form the activated layer 130. An additional embodiment may also include laser ablating the dielectric layer 101 to form the pattern with a first laser, and then using the first laser in a second pass to perform the localized activation of the patterned surfaces 145. In an embodiment, the laser ablation may be performed with a first laser and a second laser may follow the first laser and perform the localized activation of the patterned surfaces 145.

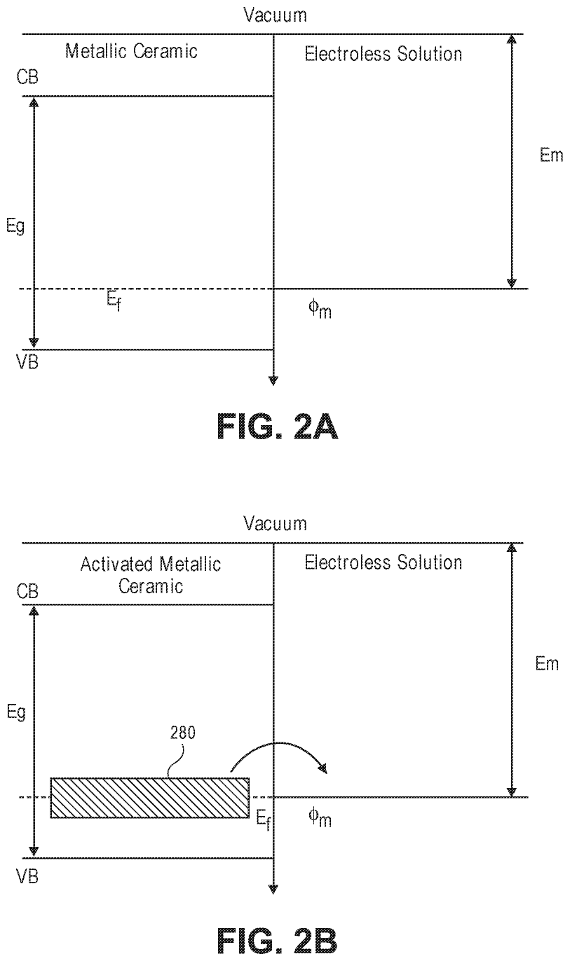

Referring now to FIGS. 2A and 2B, band diagrams of a metallic ceramic and an electroless solution are shown before and after activation, respectively. As illustrated in FIG. 2A, at equilibrium, the fermi energy E_{f} of the metallic ceramic may be approximately equal to the redox deposition potential Eₘ of the metal to be deposited when the metallic ceramic is brought in contact with the electroless solution. However, the metal deposition is not catalyzed due to the lack of an electron transfer mechanism.

Accordingly, embodiments of the invention include an activation process, such as laser ablation, that activates the metallic ceramic fillers by reducing the metallic ceramic material to a metal or by increasing the electronic density states. Particularly, embodiments include a laser assisted activation process that results in local melting, heating, and/or redeposition of metal ceramic filler particles. This generates a higher metal to oxygen ratio because of thermal dissociation and creation of oxygen defects and/or vacancies. Furthermore, recombination of created oxygen vacancies is limited by diffusion, thereby freezing the metal to oxygen ratio. Additionally, laser ablation of metallic ceramics may result in the creation of other localized defects (e.g., mid-gap states, F centers, etc.) and/or band bending (due to stress) that can increase the localized density of electrons. As illustrated in FIG. 2B, the localized defects 280 can catalyze metal deposition from electroless solution by providing an electron transfer mechanism (as indicated by the arrow) since the energy level of the localized defects 280 are approximately the same as the potential of electroless metal reduction Eₘ.

In an exemplary embodiment, Al₂O₃ may be used as the metallic ceramic filler to enable copper deposition with an electroless process. In such an embodiment, Al₂O₃ has a band gap of around 10 eV and Cu has a redox potential of 0.159V (i.e., −2 e⁻×0.159V=−0.318 eV). Laser assisted activation of Al₂O₃ generates defect states 280 that have an energy approximately equal to −0.318 eV. As such, electrons are available for the reduction of metal ions and allows for the plating of the copper with an electroless plating solution. While the activation and deposition process is described with Al₂O₃ filler particles and Cu deposition, it is to be appreciated that any metallic ceramic filler (e.g., Al₂O₃, AlN, CeO₂, ZrO₂, or the like) may be used so long as it creates localized electronic states post laser ablation that can initiate selective electroless plating of the desired metal (e.g., Cu, Ni, Pd, Au, or the like).

Referring now to FIG. 1C, the dielectric layer 101 is metallized with an electroless plating process. Since the activated layer 130 is selectively formed only along the patterned surfaces, metal is only deposited on those surfaces. According to an embodiment, the electroless plating process deposits metal into vias 110 and line openings 114 to form conductive vias 131 and traces 134, respectively. As shown in FIG. 1C, the top surfaces of the vias 131 and the traces 134 may be substantially coplanar with the top of the unpatterned surfaces 155 of the dielectric layer 101. In an embodiment, the bath used for the electroless plating process may be a solution comprising a source of metal ions, and a reducing agent. By way of example, and not by way of limitation, the metal ions may be copper ions. In an embodiment, the reducing agent may be formaldehyde or dimethylamine borane (DMAB). According to embodiments, the electroless plating solution may also comprise complexants, buffers, stabilizers, and/or accelerators, as is known in the art. Accordingly, the FCSP process described with respect to FIGS. 1A-1C may be used to selectively plate only the patterned surfaces of a dielectric layer.

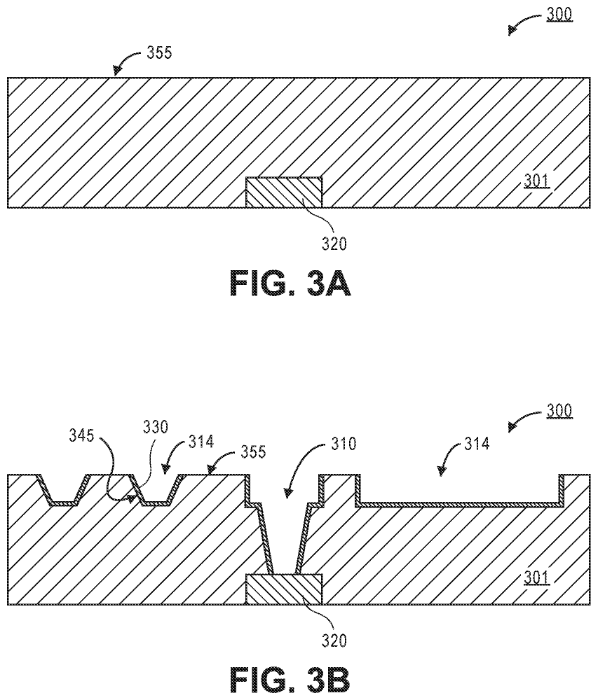

Additional embodiments of the invention may also include an incremental FCSP process. In such embodiments, the metal deposition used to form the vias is performed in a different processing operation than the metal deposition used to form the traces. Particularly, the metal deposition to form the vias is implemented with a bottom-up deposition process. Utilizing a bottom-up deposition process enables the formation of high aspect ratio vias that are substantially free of voids. In contrast, selective deposition of metal in the patterned features with a single deposition process may result in voids in the vias when the aspect ratio is too high. The voids may form because the deposition occurs along all surfaces of the via opening (i.e., the bottom surface and the sidewalls). As such, the metal deposited on the sidewalls may grow at a rate that causes the metal to pinch together prior to the complete filling of the via opening, therefore forming an internal void in the via. FIGS. 3A-3E are cross-sectional illustrations of a processing operation that may be used to implement an incremental deposition process that reduces the formation of voids in the vias, according to an embodiment of the invention.

Referring now to FIG. 3A, a cross-sectional illustration of a build-up structure 300 is shown, according to an embodiment. The build-up structure 300 includes a dielectric layer 301 formed over a contact 320. In an embodiment, the dielectric layer 301 has a top unpatterned surface 355. Embodiments of the invention include a build-up structure 300 that is substantially similar to the build-up structure 100 described above, and therefore a detailed description of the materials and structure of the build-up structure 300 is omitted.

Similar to build-up structure 100, embodiments of the invention include a build-up structure 300 that includes metallic ceramic fillers that are dispersed through the dielectric layer 301. The metallic ceramic fillers may be mixed into the dielectric material while the dielectric material is in a liquid phase prior to being deposited onto the build-up structure 100. According to an embodiment, the concentration of the metallic ceramic fillers may be approximately 1% (by weight) or less. In embodiments, the metallic ceramic fillers are materials that, when activated, include mid-gap defect states that have an energy state that is approximately equal to the redox potential of a subsequently plated metal. In an embodiment, the metallic ceramic fillers may include one or more of Al₂O₃, AlN, CeO₂, ZrO₂, and the like. In a particular embodiment, the metallic ceramic fillers are chosen such that mid-gap defect states have an energy state that is not approximately equal to the redox potential of a first metal deposited with a bottom-up deposition process used to form the vias, but is approximately equal to the redox potential of a second metal deposited onto the dielectric layer to form a seed layer. Alternatively, the traces and the pad can be formed/patterned after the bottom via plating. As such, embodiments allow the first metal to be plated in the via opening through a bottom-up deposition process that limits deposition and growth from the sidewalls of the via opening, and thereafter, a seed layer may be formed in the line openings. The seed layer may then be used to catalyze deposition of a conductive material used to form the traces.

Referring now to FIG. 3B, a cross-sectional illustration of the build-up structure 300 after portions of the unpatterned surface 355 of the dielectric layer 301 are patterned with a patterning process to form patterned surfaces 345 in the dielectric layer 301 is shown, according to an embodiment of the invention. According to an embodiment, the pattern may comprise one or more via openings 310 that provide an opening through dielectric layer 301 to the electrical contact 320 formed on a lower layer and/or one or more line openings 314. According to embodiments, the pattern may be formed with a patterning process such as direct laser writing, laser projection patterning, plasma etching, or other known patterning processes.

In an embodiment, the via openings 310 may be formed with a first patterning process, and the line openings 314 may be formed with a second patterning process. The first patterning process used to form the via openings 310 may be a different patterning process than the second patterning process. For example, the first patterning process may include laser ablation, and the second patterning process may include a plasma etching process. Additional embodiments include first and second patterning processes that are the same process. For example, both the first and second patterning processes may include a laser ablation process. According to such an embodiment, the laser intensity may be the same for the first and second patterning processes. Alternatively, the first and second patterning processes may use different laser intensities. In an embodiment, the intensity of a laser for a direct laser writing process may be between 0.5 J/cm² and 3 J/cm². In an additional embodiment, the via openings 310 and the line openings 314 may be formed with a single patterning process.

According to an embodiment, laser assisted local activation may activate the metallic ceramic fillers that are included in the dielectric layer 301. Accordingly, an activated layer 330 is illustrated as being formed over the patterned surfaces 345. Using laser assisted local activation allows for the activated layer 330 to be selectively formed only on the patterned surfaces 345 of the dielectric layer 301. According to an embodiment, laser assisted local activation is performed during the patterning process to form the activated layer 330 or laser assisted local activation may be performed after the patterning process.

According to an embodiment, the laser assisted local activation of the patterned surfaces 345 activates the metallic ceramic fillers by reducing the metallic ceramic material to a metal or by increasing the electronic density states. For example, laser ablation of metal based ceramics such as Al₂O₃, AlN, CeO₂, ZrO₂, and the like results in creation of localized defects (e.g., oxygen vacancies, mid gap states, F centers) and/or band bending (due to stress) that can increase the localized density of electrons. The electroless metal deposition of a subsequently formed seed layer is enabled by these electronic states when the electronic states are approximately the same as the potential of electroless metal reduction of the metal used to form the seed layer.

Referring now to FIG. 3C, a cross-sectional illustration of the build-up structure 300 is shown after a first metal deposition process is used to form the vias 331, according to an embodiment of the invention. According to an embodiment, the first metal deposition process is an electroless process that is not catalyzed by the activated surface 330. Instead, the exposed surface of the conductive pad 320 allows for deposition of the via 331 to progress in a bottom-up manner. Since the activated surfaces 330 do not include defects states with the proper energy level for catalyzing the reduction of the first metal, there is no deposition along the sidewalls of the via opening 310, and the formation of voids in the via 331 is substantially avoided. Additionally, the lack of a catalyst in the line openings 314 prevents deposition of the first metal in the line openings 314 as well.

Referring now to FIG. 3D, a cross-sectional illustration of the build-up structure 300 is shown after a seed layer 333 is formed on the exposed activated surfaces 330, according to an embodiment of the invention. In an embodiment, the seed layer 333 is formed from a metal that has a reduction potential that is approximately equal to the energy state of the mid-gap defects in the activated surface 330. Accordingly, the mid-gap defects provide an electron transfer mechanism that allows for the reduction of the metal ions in an electroless solution to form the seed layer 333 selectively over the exposed portions of the patterned surfaces 345.

Referring now to FIG. 3E, a cross-sectional illustration of the build-up structure 300 is shown after the second metal deposition process is used to form the traces 334 in the line openings 314. Since the seed layer 333 is selectively formed only along the patterned surfaces 345, metal is only deposited on those surfaces since there is no catalyst to drive the deposition reaction on the unpatterned surfaces 355. In an embodiment, the bath used for the electroless plating process may be a solution comprising a source of metal ions, and a reducing agent. By way of example, and not by way of limitation, the metal ions may be copper ions. In an embodiment, the reducing agent may be formaldehyde or dimethylamine borane (DMAB). According to embodiments, the electroless plating solution may also comprise complexants, buffers, stabilizers, and/or accelerators, as is known in the art.

In FIGS. 3A-3E, the incremental deposition process is described in general terms in order to indicate that any combination of materials for the metallic ceramic fillers, seed layers, and deposited metals may be used so long as the activated metallic ceramic fillers only catalyze the deposition of the seed layer and not the deposition of the metals used to form the vias 331. For example, depending on the metal being deposited to form the vias 331, the metallic ceramic filler may be one or more of Al₂O₃, AlN, CeO₂, ZrO₂, and the like. In a particular embodiment, using CeO₃ metallic ceramic fillers allows for Cu to be deposited to form the vias 331 and a Pd seed layer to be formed after the vias 331 are formed. For example, CeO₂ fillers have been known to selectively activate electroless plating of Pd from a PdCl₂ solution in accordance with Equation 1.

$$2 {Pd ( {NH}_{3} )}_{4}^{2 +} + {N}_{2} {H}_{4} + 4 {OH}^{-} {\to }^{{CeO}_{2}} 2 {Pd}^{0} + 8 {NH}_{3} + {N}_{2} + 4 {H}_{2} O \qquad Equation 1$$

Furthermore, no Pd deposition occurs in the absence of activated CeO₂ metallic ceramic fillers. Similar to Al₂O₃ fillers described above, laser ablation of CeO₂ creates oxygen vacancies and Ce³⁺ ions that act as catalytic centers for Pd deposition from the corresponding electroless solution. In this case, the energy level of the localized defect is comparable to the redox potential of Pd reduction and hydrazine hydrate oxidation. Additionally, the band gap of CeO₂ (approximately 3.1 eV) is less than the band gap of Al₂O₃ (approximately 10 eV). Accordingly, the oxygen vacancy defects in activated CeO₂ have a faster recombination time and lower energy, thereby eliminating the possibility of activating Cu reduction and deposition due to the higher desired deposition potential needed to deposit Cu.

As such, after the activated layer 330 has been formed, the first metal deposition process may plate the Cu bottom-up from the contact 320 exposed by the via opening 310 to form the via 331 with substantially no voids. Thereafter, a Pd seed layer 333 may be formed over patterned surfaces 345 using the activated CeO₂ as a catalyst. Subsequent to the formation of the Pd seed layer 333, the Cu traces 334 may be deposited with an electroless process that utilizes the Pd seed layer 333 as the catalyst. Accordingly, the conductive features in the build-up structure 300 may include a via 331 that is formed without a seed layer and traces 334 that are formed over the seed layer 333.

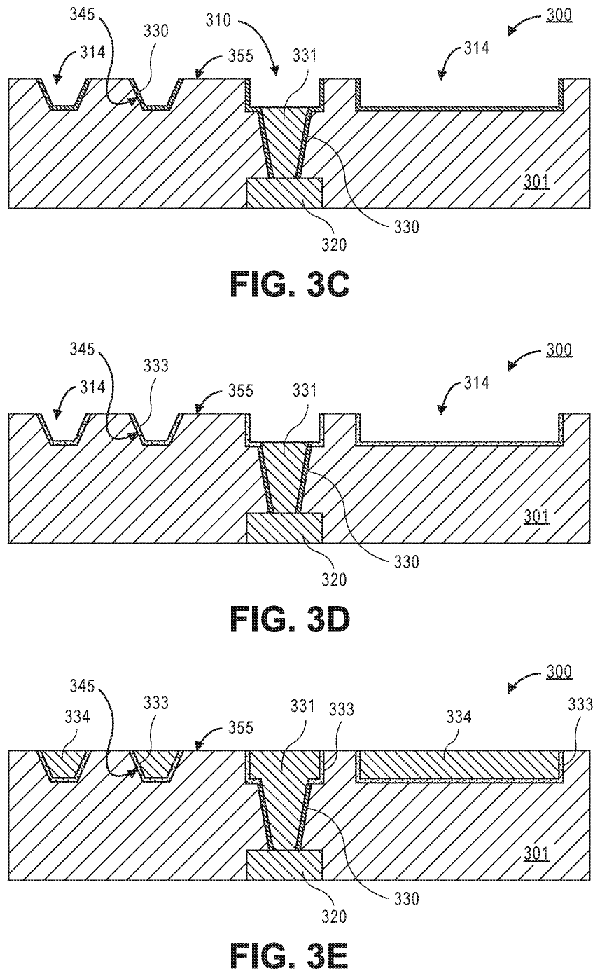

Referring now to FIG. 4, a plan view illustration of a panel 400 including multiple build-up structures 100 and/or 300 is shown, according to an embodiment of the invention. Each build-up structure 100/300 may include a plurality of dielectric layers 101, 301, formed in accordance with embodiments of the invention. Accordingly, a plurality of build-up structures may be manufactured simultaneously. As shown, each build-up structure 100/300 may be separated by scribe lines 460 to allow for singulation after the build-up structures 100 or 300 have been manufactured.

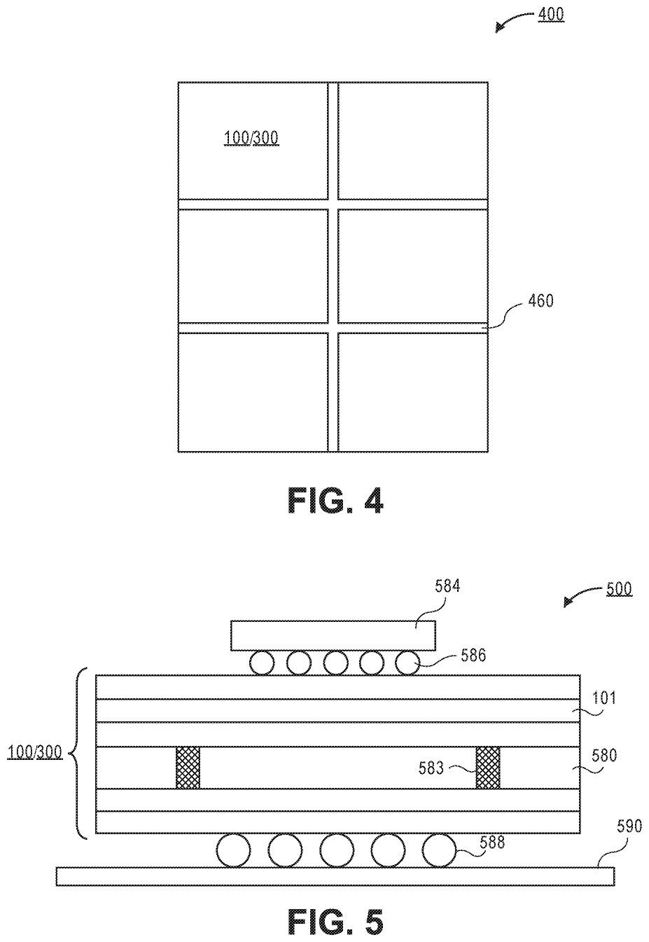

Referring now to FIG. 5, a cross-sectional illustration of a package 500 that includes a build-up structure 100 and/or 300 is shown, according to an embodiment of the invention. According to an embodiment, the build-up structure 100/300 includes one or more dielectric layers 101 formed in accordance with embodiments. As such, each dielectric layer 101 may include electrical interconnects, such as conductive traces and vias, as described above. For example, the conductive traces and vias may be formed with a FCSP process or an incremental FCSP process, such as those described above. In an embodiment, the build-up structure 100/300 may include a core 580, although other embodiments may include a coreless design. The core 580 includes vias 583 that allow electrical connections to be made through the build-up structure 100/300. As shown, a chip 584, such as a flip-chip, is connected to a build-up structure 100 with solder bumps 586. The lowermost dielectric layer 101 of the build-up structure 100 may be bonded to a board 590, such as a printed circuit board, with solder bumps 588.

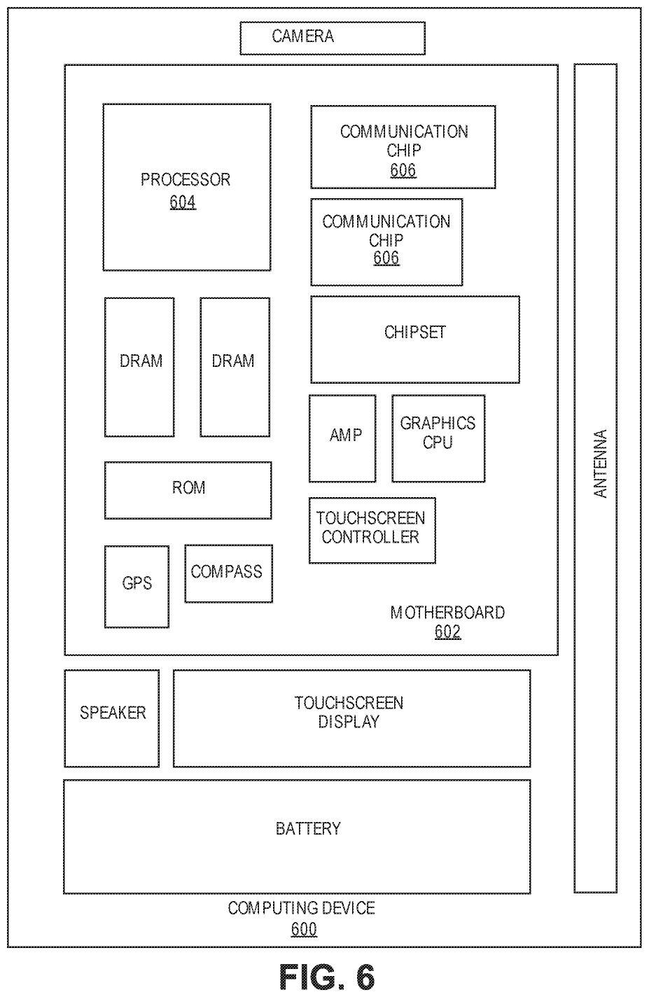

FIG. 6 illustrates a computing device 600 in accordance with an embodiment. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations, the processor 604 is integrated into a package that includes one or more build-up structures that have dielectric layers that are selectively metalized in accordance with various embodiments. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another embodiment, the communication chip 606 may be integrated into a package that includes one or more build-up structures that have dielectric layers that are selectively metalized in accordance with various embodiments.

In further implementations, another component housed within the computing device 600 that may be integrated into a package that includes one or more build-up structures that have dielectric layers that are selectively metalized in accordance with various embodiments.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

Example 1: a method of forming a build-up structure, comprising: patterning a dielectric layer to form patterned surfaces in the dielectric layer, wherein the dielectric layer includes metallic ceramic fillers; activating the metallic ceramic fillers to form activated surfaces over the patterned surfaces, wherein the activated metallic ceramic fillers include mid-gap states; and selectively depositing a metal over the activated surfaces with an electroless deposition process, wherein the mid-gap states have an energy level approximately equal to a reduction potential of metal ions in an electroless solution.

Example 2: the method of Example 1, wherein activating the metallic ceramic fillers includes laser assisted localized activation.

Example 3: the method of Example 2, wherein the laser assisted localized activation is performed concurrently with the patterning of the dielectric layer.

Example 4: the method of Example 2, wherein the laser assisted localized activation is performed subsequent to the patterning of the dielectric layer.

Example 5: the method of Example 1, Example 2, Example 3, or Example 4, wherein patterning the dielectric layer includes forming one or more via openings and one or more line openings.

Example 6: the method of Example 1, Example 2, Example 3, Example 4, or Example 5, wherein selectively depositing the metal over the patterned surfaces produces conductive traces and vias in the build-up structure.

Example 7: the method of Example 1, Example 2, Example 3, Example 4, Example 5, or Example 6, wherein the metallic ceramic fillers include one or more of Al₂O3, AlN, CeO₂, and ZrO₂.

Example 8: the method of Example 1, Example 2, Example 3, Example 4, Example 5, Example 6, or Example 7, wherein the deposited metal is Cu, Ni, Au, or Pd.

Example 9: the method of Example 1, Example 2, Example 3, Example 4, Example 5, Example 6, Example 7, or Example 8, wherein the metallic ceramic fillers are Al₂O₃, and the deposited metal is Cu.

Example 10: the method of Example 1, Example 2, Example 3, Example 4, Example 5, Example 6, Example 7, Example 8, or Example 9, wherein the via opening exposes a top surface of a conductive pad.

Example 11: a method of forming a build-up structure, comprising: patterning a dielectric layer to form patterned surfaces in the dielectric layer, wherein the dielectric layer includes metallic ceramic fillers, and wherein the patterned surfaces form a line opening and a via opening that exposes a conductive pad; activating the metallic ceramic fillers to form activated surfaces over the patterned surfaces, wherein the activated metallic ceramic fillers include mid-gap states; depositing a first metal into the via opening with a first electroless solution, wherein the deposition is a bottom-up deposition process, and wherein the first metal is not deposited in the line opening; forming a seed layer over the exposed portions of the activated surfaces, wherein the mid-gap states have an energy level approximately equal to a reduction potential of metal ions in a second electroless solution used to form the seed layer; and depositing a second metal into the via opening with a third electroless solution.

Example 12: the method of Example 11, wherein the mid-gap states have an energy level less than a reduction potential of metal ions in the first electroless solution.

Example 13: the method of Example 11 or Example 12, wherein the metallic ceramic fillers are CeO₂.

Example 14: the method of Example 11, Example 12, or Example 13, wherein the seed layer is Pd, and wherein the first and second metals are Cu.

Example 15: the method of Example 11, Example 12, Example 13, or Example 14, wherein activating the metallic ceramic fillers includes laser assisted localized activation.

Example 16: the method of Example 11, Example 12, Example 13, Example 14, or Example 15, wherein the laser assisted localized activation is performed concurrently with the patterning of the dielectric layer.

Example 17: the method of Example 11, Example 12, Example 13, Example 14, or Example 15, wherein the laser assisted localized activation is performed subsequent to the patterning of the dielectric layer.

Example 18: a build-up structure comprising: a dielectric layer with metallic ceramic fillers distributed throughout the dielectric layer; a via formed through the dielectric layer, wherein the via includes a single conductive material; and a conductive trace formed into the dielectric layer, wherein the conductive trace includes a seed layer in direct contact with the dielectric layer and a bulk conductive material over the seed layer.

Example 19: the build-up structure of Example 18, wherein the metallic ceramic fillers form mid-gap states when activated by a localized laser activation process.

Example 20: the build-up structure of Example 19, wherein the mid-gap states have an energy level approximately equal to the redox potential of metal ions used to form the seed layer.

Example 21: the build-up structure of Example 18, Example 19, or Example 20, wherein the metallic ceramic fillers are CeO₂, and wherein the seed layer is Pd.

Example 22: the build-up structure of Example 18, Example 19, Example 20, or Example 21, wherein the via is Cu and the bulk conductive material of the conductive trace is Cu.

Example 23: a packaged system, comprising: a printed circuit board; a build-up structure mounted to the printed circuit board with solder bumps, wherein the build-up structure comprises: a plurality of dielectric layers with metallic ceramic fillers distributed throughout each dielectric layer; one or more vias formed through at least one of the dielectric layers, wherein the vias include a single conductive material; and one or more conductive traces formed into at least one of the dielectric layers, wherein the conductive traces include a seed layer in direct contact with the dielectric layer and a bulk conductive material over the seed layer; and a semiconductor die mounted to and electrically coupled to the build-up structure.

Example 24: the packaged system of Example 23, wherein the metallic ceramic fillers form mid-gap states when activated by a localized laser activation process, and wherein the mid-gap states have an energy level approximately equal to the redox potential of metal ions used to form the seed layer.

Example 25: the packaged system of Example 23 or Example 24, wherein the metallic ceramic fillers are CeO₂, wherein the seed layer is Pd, wherein the via is Cu, and wherein the bulk conductive material of the conductive traces is Cu.

What is claimed is:

1. A method of forming a build-up structure, comprising:
patterning a dielectric layer to form patterned surfaces in the dielectric layer, wherein the dielectric layer includes metallic ceramic fillers;
activating the metallic ceramic fillers to form activated surfaces over the patterned surfaces, wherein the activated metallic ceramic fillers include mid-gap states; and
selectively depositing a metal over the activated surfaces with an electroless deposition process, wherein the mid-gap states have an energy level approximately equal to a reduction potential of metal ions in an electroless solution.

2. The method of claim 1, wherein activating the metallic ceramic fillers includes laser assisted localized activation.

3. The method of claim 2, wherein the laser assisted localized activation is performed concurrently with the patterning of the dielectric layer.

4. The method of claim 2, wherein the laser assisted localized activation is performed subsequent to the patterning of the dielectric layer.

5. The method of claim 1, wherein patterning the dielectric layer includes forming one or more via openings and one or more line openings.

6. The method of claim 5, wherein selectively depositing the metal over the patterned surfaces produces conductive traces and vias in the build-up structure.

7. The method of claim 6, wherein the metallic ceramic fillers include one or more of Al₂O₃, AlN, CeO₂, and ZrO₂.

8. The method of claim 7, wherein the deposited metal is Cu, Ni, Au, or Pd.

9. The method of clam 8, wherein the metallic ceramic fillers are Al₂O₃, and the deposited metal is Cu.

10. The method of claim 5, wherein the via opening exposes a top surface of a conductive pad.

11. A method of forming a build-up structure, comprising:
patterning a dielectric layer to form patterned surfaces in the dielectric layer, wherein the dielectric layer includes metallic ceramic fillers, and wherein the patterned surfaces form a line opening and a via opening that exposes a conductive pad;
activating the metallic ceramic fillers to form activated surfaces over the patterned surfaces, wherein the activated metallic ceramic fillers include mid-gap states;
depositing a first metal into the via opening with a first electroless solution, wherein the deposition is a bottom-up deposition process, and wherein the first metal is not deposited in the line opening;
forming a seed layer over the exposed portions of the activated surfaces, wherein the mid-gap states have an energy level approximately equal to a reduction potential of metal ions in a second electroless solution used to form the seed layer; and
depositing a second metal into the via opening with a third electroless solution.

12. The method of claim 11, wherein the mid-gap states have an energy level less than a reduction potential of metal ions in the first electroless solution.

13. The method of claim 12, wherein the metallic ceramic fillers are CeO₂.

14. The method of claim 12, wherein the seed layer is Pd, and wherein the first and second metals are Cu.

15. The method of claim 11, wherein activating the metallic ceramic fillers includes laser assisted localized activation.

16. The method of claim 15, wherein the laser assisted localized activation is performed concurrently with the patterning of the dielectric layer.

17. The method of claim 15, wherein the laser assisted localized activation is performed subsequent to the patterning of the dielectric layer.

18. A build-up structure comprising:
a dielectric layer with metallic ceramic fillers distributed throughout the dielectric layer;
a via formed through the dielectric layer, wherein the via includes a single conductive material; and
a conductive trace formed into the dielectric layer, wherein the conductive trace includes a seed layer in direct contact with the dielectric layer and a bulk conductive material over the seed layer.

19. The build-up structure of claim 18, wherein the metallic ceramic fillers form mid-gap states when activated by a localized laser activation process.

20. The build-up structure of claim 19, wherein the mid-gap states have an energy level approximately equal to the redox potential of metal ions used to form the seed layer.

21. The build-up structure of claim 20, wherein the metallic ceramic fillers are CeO₂, and wherein the seed layer is Pd.

22. The build-up structure of claim 21, wherein the via is Cu and the bulk conductive material of the conductive trace is Cu.

23. A packaged system, comprising:
a printed circuit board;
a build-up structure mounted to the printed circuit board with solder bumps, wherein the build-up structure comprises:
a plurality of dielectric layers with metallic ceramic fillers distributed throughout each dielectric layer;
one or more vias formed through at least one of the dielectric layers, wherein the vias include a single conductive material; and
one or more conductive traces formed into at least one of the dielectric layers, wherein the conductive traces include a seed layer in direct contact with the dielectric layer and a bulk conductive material over the seed layer; and
a semiconductor die mounted to and electrically coupled to the build-up structure.

24. The packaged system of claim 23, wherein the metallic ceramic fillers form mid-gap states when activated by a localized laser activation process, and wherein the mid-gap states have an energy level approximately equal to the redox potential of metal ions used to form the seed layer.

25. The packaged system of claim 24, wherein the metallic ceramic fillers are CeO₂, wherein the seed layer is Pd, wherein the via is Cu, and wherein the bulk conductive material of the conductive traces is Cu.
